(19) United States
(12) Patent Application Publication
(10) Pub. No.: US 2025/0176256 A1
(43) Pub. Date: May 29, 2025

(54) BRIDGE STRUCTURE FOR DIFFERENT THRESHOLD-VOLTAGE DEVICES

(71) Applicant: QUALCOMM Incorporated, San Diego, CA (US)

(72) Inventors: Kaushik BARUAH, Bangalore (IN); Srinivasulu JANAMALA, Hyderabad (IN); Thomas Hua-Min WILLIAMS, Irvine, CA (US); Joshua PAIK, Laguna Hills, CA (US)

(21) Appl. No.: 18/521,769

(22) Filed: Nov. 28, 2023

(51) Int. Cl. H01L 27/092; H01L 29/06

(52) U.S. Cl. CPC H10D 84/856; H10D 62/10

(57) ABSTRACT

A chip includes a first active device having a first threshold voltage, and a second active device having a second threshold voltage, wherein the first threshold voltage is higher than the second threshold voltage. The chip also includes a bridge structure between the first active device and the second active device. The bridge structure includes a first single diffusion break (SDB), a second SDB, and a first diffusion region extending in a first direction between the first SDB and the second SDB.

### BACKGROUND

### Field

Aspects of the present disclosure relate generally to chip layout, and more particularly, to a bridge for different threshold-voltage devices.

### Background

A chip may include many active devices (e.g., transistors), which may be interconnected to provide various circuits on the chip including analog circuits, mixed-signal circuits, digital circuits, and the like. The process technology used to fabricate the chip may support devices (e.g., transistors) with different threshold voltages. This allows an integrated circuit on the chip to include a mix of devices with different threshold voltages.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

An aspect relates to a chip. The chip includes a first active device having a first threshold voltage, and a second active device having a second threshold voltage, wherein the first threshold voltage is higher than the second threshold voltage. The chip also includes a bridge structure between the first active device and the second active device. The bridge structure includes a first single diffusion break (SDB), a second SDB, and a first diffusion region extending in a first direction between the first SDB and the second SDB.

### BRIEF DESCRIPTION OF THE DRAWINGS

FIG. 1A shows a side view of an example of a chip including an active device and multiple topside layers according to certain aspects of the present disclosure.

FIG. 1B shows a side view of the chip of FIG. 1A further including backside metal layers according to certain aspects of the present disclosure.

FIG. 1C shows a side view of the active of FIG. 1A implemented with a gate-all-around (field effect transistor) FET according to certain aspects of the present disclosure.

FIG. 1D shows a perspective view of the active device implemented with the gate-all-around FET according to certain aspects of the present disclosure.

FIG. 1E shows a perspective view of the active device implemented with a FinFET according to certain aspects of the present disclosure.

FIG. 2A shows a top view of an example of a double diffusion break according to certain aspects of the present disclosure.

FIG. 2B shows a side view of the double diffusion break according to certain aspects of the present disclosure.

FIG. 3A shows a top view of an example of a single diffusion break according to certain aspects of the present disclosure.

FIG. 3B shows a side view of the single diffusion break according to certain aspects of the present disclosure.

FIG. 4A shows a top view of an example of a bridge structure between a first active device and a second active device according to certain aspects of the present disclosure.

FIG. 4B shows a side view of the bridge structure of FIG. 4A according to certain aspects of the present disclosure.

FIG. 5 shows a top view of an exemplary layout of uniformly spaced gates according to certain aspects of the present disclosure.

FIG. 6 shows an example of vias disposed on contacts and gates of the first active device and the second active device according to certain aspects of the present disclosure.

FIG. 7 shows an example of the bridge structure between a third active device and a fourth active device according to certain aspects of the present disclosure.

FIG. 8 is a block diagram illustrating a computer system according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

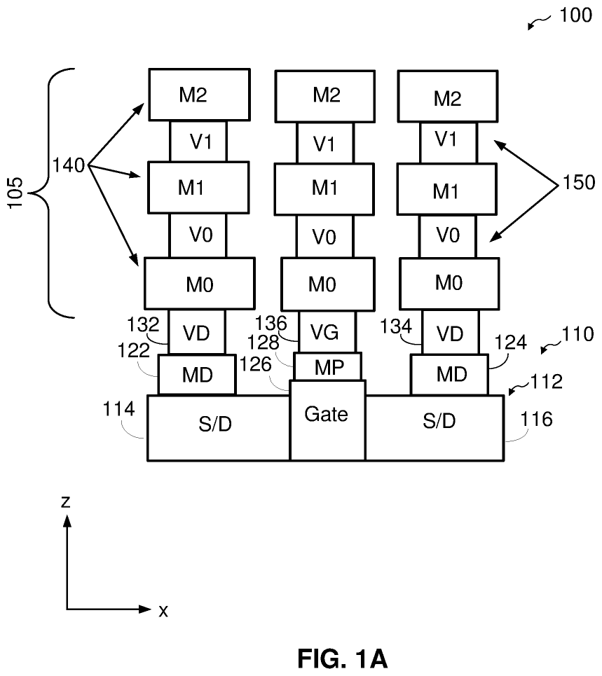

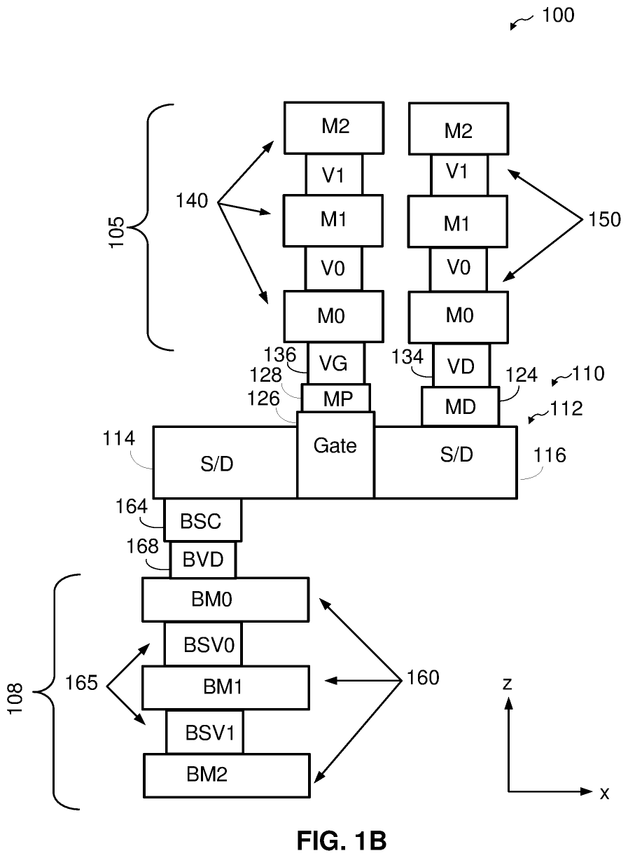

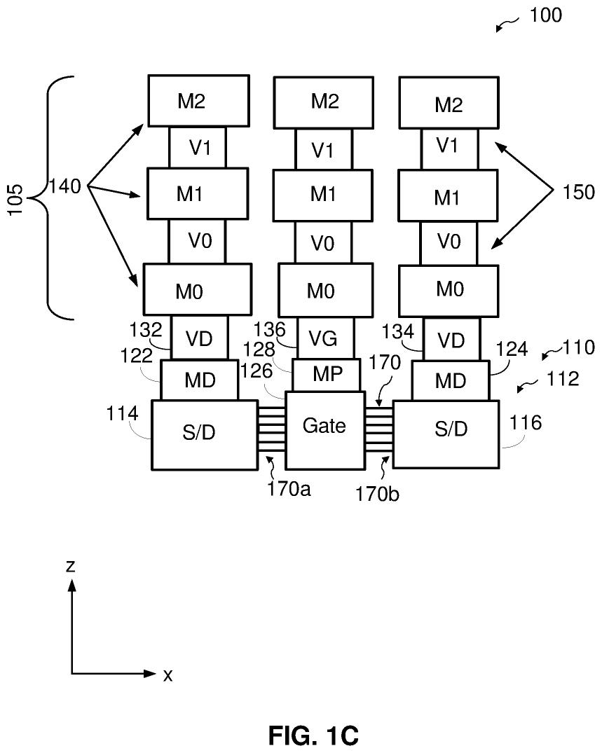

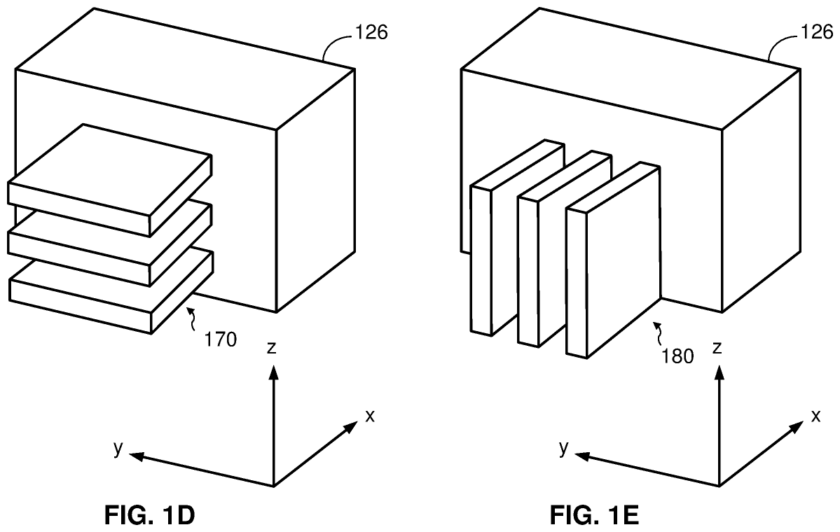

FIG. 1A shows a side view of an example of a chip 100 (e.g., a die) including an active device 110 (e.g., transistor) and multiple topside layers 105 above the active device 110 according to certain aspects. Although one active device 110 is shown in FIG. 1A for simplicity, it is to be appreciated that the chip 100 includes many active devices. As discussed further below, the active device 110 may be implemented using a fin field-effect transistor (FinFET) process, a gate-all-around FET process, or another type of process.

In the example shown in FIG. 1A, the active device 110 includes a diffusion region 112 and a gate 126 on the diffusion region 112. The diffusion region 112 may also be referred to as an oxide diffusion region, an active region, active diffusion, active (RX), active layer, or another term. The gate 126 may include polysilicon, one or more gate metals, and/or another gate material. In the example shown in FIG. 1A, a portion of the diffusion region 112 to the left of the gate 126 provides a first source/drain 114 of the active device 110, and a portion of the diffusion region 112 to the right of the gate 126 provides a second source/drain 116 of the active device 110. As used herein, the term “source/drain” means a source, a drain, or both a source and a drain. In this example, the gate 126 controls the conductivity between the first source/drain 114 and the second source/drain 116 based on a voltage applied to the gate 126. The active device 110 may be a p-type transistor in which the diffusion region 112 is a p-type diffusion region, or the active device 110 may be an n-type transistor in which the diffusion region 112 is an n-type diffusion region.

In this example, the chip 100 includes a contact 122 formed on a top surface of the first source/drain 114, and a contact 124 formed on a top surface of the second source/drain 116. A top surface may also be referred to as a frontside surface. The contacts 122 and 124 may be formed (i.e., patterned) from a contact layer using, for example, lithographic and etching processes. Each contact 122 and 124 may be referred to as a metal-diffusion (MD) contact, contact active (CA), or another term. The chip 100 may also include a gate contact 128 formed on the gate 126. The gate contact 128 may be referred to as a metal-poly (MP) contact or another term. The gate contact 128 may be omitted in some implementations.

In this example, the topside layers 105 include topside metal layers 140. The topside metal layers 140 may be patterned (e.g., using lithography and etching) to provide signal routing for the active device 110 and other active devices (not shown in FIG. 1A) integrated on the chip 100. In some implementations, the topside metal layers 140 may also be patterned to form a power distribution network for distributing power to the active device 110 and other active devices integrated on the chip 100.

In the example in FIG. 1A, the bottom-most metal layer is referred to as metal layer M0. The metal layer immediately above metal layer M0 is referred to as metal layer M1, the metal layer immediately above metal layer M1 is referred to as metal layer M2, and so forth. Although three metal layers 140 (i.e., M0 to M2) are shown in FIG. 1A for ease of illustration, it is to be appreciated that the topside layers 105 may include additional metal layers above metal layer M2. It is to be appreciated that the present disclosure is not limited to the nomenclature in which the bottom-most metal layer is referred to as metal layer M0. For instance, in another example, the bottom-most metal layer may be referred to as metal layer M1 instead of metal layer M0.

The topside layers 105 also includes vias 150 that provide coupling between the topside metal layers 140. In this example, the vias V0 provide coupling between metal layer M0 and metal layer M1, and the vias V1 provide coupling between metal layer M1 and metal layer M2. In the example in FIG. 1A, the chip also includes a via 136 disposed between the gate contact 128 and metal layer M0, in which the via 136 couples the gate contact 128 (and hence the gate 126) to metal layer M0. For implementations where the gate contact 128 is omitted, the via 136 may be disposed between the gate 126 and metal layer M0 without an intervening gate contact. Also, in this example, the chip 100 includes a via 132 disposed between the contact 122 and metal layer M0, and a via 134 disposed between the contact 124 and metal layer M0. The via 132 couples the contact 122 to metal layer M0, and the via 134 couples the contact 124 to metal layer M0.

In certain aspects, the chip 100 may also include backside layers 108 below the active device 110, as shown in the example in FIG. 1B. For example, the backside layers 108 may be used to form a power distribution network for distributing power to the active device 110 and other active devices integrated on the chip 100 (e.g., to reduce signal routing congestion in metal layer M0). In this example, the backside layers 108 include backside metal layers 160, which may be patterned (e.g., using lithography and etching) to form the power distribution network discussed above.

In the example in FIG. 1B, the top-most backside metal layer is referred to as backside metal layer BM0. The backside metal layer immediately below backside metal layer BM0 is referred to as backside metal layer BM1, the backside metal layer immediately below backside metal layer BM1 is referred to as backside metal layer BM2, and so forth. Although three backside metal layers 160 (i.e., BM0 to BM2) are shown in FIG. 1B for ease of illustration, it is to be appreciated that the backside layers 108 may include additional metal layers below backside metal layer BM2.

In the example in FIG. 1B, the chip 100 includes a backside contact 164 formed on a bottom surface (i.e., backside surface) of the first source/drain 114. The backside contact 164 may be formed (i.e., patterned) from a backside contact layer (labeled “BSC”). The chip 100 may also include backside via 168 disposed between the backside contact 164 and backside metal layer BM0 to couple the backside contact 164 to backside metal layer BM0. The backside layers 108 include vias 165 that provide coupling between the backside metal layers 160.

As discussed above, the active device 110 may be implemented using a FinFET process, a gate-all-around FET process, or another type of process. FIG. 1C shows an example in which the active device 110 is implemented using a gate-all-around FET process. In this example, the diffusion region 112 includes vertically stacked channels 170 (e.g., nanosheets) in which the gate 126 may surround each of the channels 170 on four sides. The first source/drain 114 and the second source/drain 116 may each include epitaxially grown or deposited silicon, a silicon-based material (e.g., silicon-germanium), or any combination thereof. In this example, the first source/drain 114 is coupled to a first side 170a of the channels 170, and the second source/drain 116 is coupled to a second side 170b of the channels. However, it is to be appreciated that the present disclosure is not limited to this example. FIG. 1D shows a perspective view of the channels 170 and the gate 126.

FIG. 1E shows a perspective view in which the active device 110 is implemented using a FinFET process. In this example, the diffusion region 112 includes fins 180 extending in the x direction, in which the gate 126 may surround each of the fins 180 on three sides.

Although one gate 126 is shown in FIGS. 1A to 1E, it is to be appreciated that the active device 110 may include multiple gates arranged in parallel and coupled to one another (e.g., through metal layer M0). A transistor with multiple gates may be referred to as a multi-finger transistor or another term.

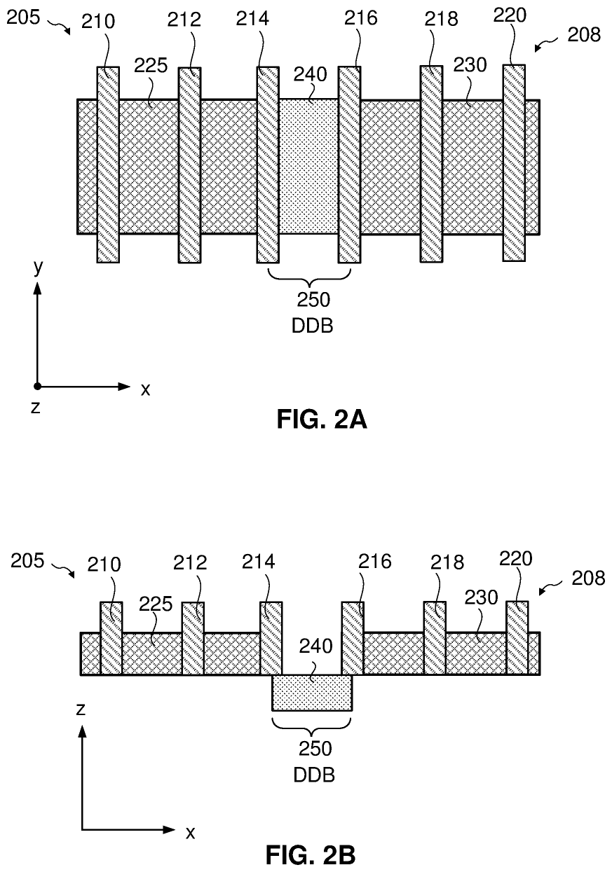

Neighboring devices and/or neighboring cells on a chip may be isolated from one another using a diffusion break. Examples of diffusion breaks include a double diffusion break (DDB) and a single diffusion break (SDB). In this regard, FIGS. 2A and 2B illustrate an exemplary DDB 250 according to certain aspects of the present disclosure. FIG. 2A shows a top view of the DDB 250 and FIG. 2B shows a side view of the DDB 250.

In this example, the DDB 250 is disposed between a first active device 205 (e.g., first transistor) and a second active device 208 (e.g., second transistor). The first active device 205 includes a first diffusion region 225 and gates 210 and 212 (e.g., active gates) extending across the first diffusion region 225. The second active device 208 includes a second diffusion region 230 and gates 218 and 220 extending across the second diffusion region 230. In this example, the DDB 250 isolates the first active device 205 from the second active device 208.

The DDB 250 includes a first dummy gate 214 and a second dummy gate 216 separated by one gate pitch (i.e., distance between adjacent gates in the x direction). The DDB 250 also includes an insulator 240 (e.g., shallow trench isolation (STI)) between the dummy gates 214 and 216. The insulator 240 may include silicon dioxide (SiO2) or another insulating material. The DDB 250 has a length in the x direction approximately to one gate pitch. The DDB 250 may be formed by etching away the diffusion region between the dummy gates 214 and 216 and forming the insulator 240 between the dummy gates 214 and 216.

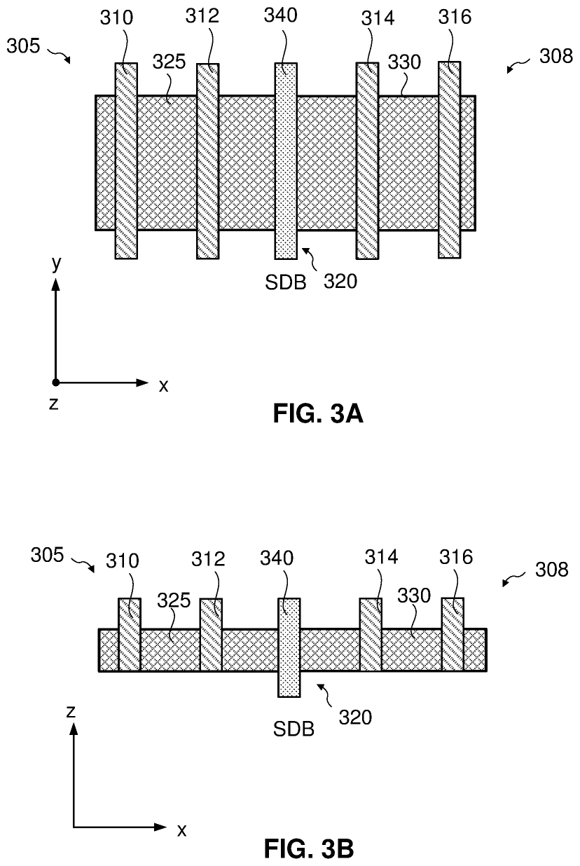

FIGS. 3A and 3B illustrate an exemplary SDB 320 according to certain aspects of the present disclosure. FIG. 3A shows a top view of the SDB 320 and FIG. 3B shows a side view of the SDB 320. In this example, the SDB 302 is disposed between a first active device 305 (e.g., first transistor) and a second active device 308 (e.g., second transistor). The first active device 305 includes a first diffusion region 325 and gates 310 and 312 (e.g., active gates) extending across the first diffusion region 325. The second active device 308 includes a second diffusion region 330 and gates 314 and 316 extending across the second diffusion region 330. In this example, the SDB 320 isolates the first active device 305 from the second active device 308.

The SDB 320 includes an insulator 340 disposed between the first diffusion region 325 and the second diffusion region 330. The insulator 340 may include silicon nitride (SiN), silicon dioxide (SiO2), or another insulating material. The SDB 320 may be formed by etching away a sacrificial gate between the gates 312 and 314 and the diffusion region under the sacrificial gate, and filling the resulting opening or cavity with insulating material (e.g., SiN) to form the insulator 340. The SDB 320 may have a length in the x direction approximately equal to the length of one gate in the x direction.

The chip 100 may include active devices (e.g., transistors) with different threshold voltages. For example, the chip may include low threshold voltage (LVT) devices and regular threshold voltage (RVT) devices, in which the RVT devices have a higher threshold voltage than the LVT devices. In this example, the LVT devices provide higher performance (e.g., faster switching speeds) than the RVT devices while the RVT devices have lower subthreshold current leakage than the LVT devices, which translates into reduced power consumption. This allows a circuit designer to make a tradeoff between performance and power consumption. For example, the circuit designer may employ LVT devices in a critical signal path of the circuit to meet timing requirements for the circuit, and employ LVT in non-critical signal paths of the circuit to reduce power consumption. An RVT device may also be referred to as a standard VT (SVT) device or another term.

It is to be appreciated that the chip 100 is not limited to two different types of VT devices. For example, the chip 100 may include any combination of the following VT devices: ultra-low VT (ULVT) devices, super-low VT (SLVT) devices, LVT devices, RVT devices, and high VT (HVT) devices. In this example, the SLVT devices have a higher threshold voltage than the ULVT devices, the LVT devices have a higher threshold voltage than the SLVT devices, the RVT devices have a higher threshold voltage than the LVT devices, and the HVT devices have a higher threshold voltage than the RVT devices. The different types of VT devices provide the circuit designer with greater flexibility in optimizing performance and power. As used herein, a “VT device” is an active device (e.g., transistor) having a threshold voltage, in which the active device is turned on when a voltage applied to the gate of the device is above the threshold voltage. When the voltage is below the threshold voltage, the device operates in a subthreshold region and conducts subthreshold current.

In certain aspects, the gate for each VT device (e.g., transistor) may include a stack of gate metal layers. For example, the gate metal layers for each type of VT device may include any composition including one or more of the following: titanium aluminide (TiAl), titanium nitride (TiN), tantalum nitride (TaN), and the like. In these aspects, different threshold voltages for the different types of VT devices (e.g., transistors) may be achieved by varying the composition of the gate metal layers and/or varying the thicknesses of the gate metal layers. For example, the process technology used to fabricate the chip 100 may support multiple types of VT devices (i.e., devices with different threshold voltages). For each type of VT device, the process technology may define the composition and the thicknesses of the gate metal layers for the type of VT device. It is to be appreciated that the present disclosure is not limited to the above examples, and that other techniques may also be used to achieve different threshold voltages for different types of VT devices.

Laying out different types of VT devices (e.g., transistors) on the chip 100 while avoiding design rule check (DRC) violations is challenging. The DRC is used to verify that the chip layout satisfies design rules (e.g., minimum spacing requirements) defined for the process technology used to fabricate the chip 100. For example, the design rules may prohibit two VT devices of different types from abutting each other (e.g., sharing a source/drain), which places constraints on the placement of different types of VT devices on the chip 100.

One approach to avoid DRC violations is to place VT devices (e.g., transistors) of different types in different rows on the chip 100. However, this approach can lead to layout efficiencies by increasing the number of rows needed to lay out a circuit including a mix of VT devices of different types. Another approach places a tap structure (e.g., substrate tie) between two VT devices of different types to enable the placement of the VT devices in the same row. However, the tap structure can take up a relatively large area of the row, which reduces layout efficiency.

To address the above, aspects of the present disclosure provide a VT bridge structure that may be placed between two VT devices of different types to enable the placement of the VT devices in the same row. The VT bridge structure occupies less area than the tap structure discussed above, and therefore improves layout efficiency compared with using the tap structure. In certain aspects, the VT bridge structure includes a first SDB and a second SDB (e.g., a first SDB over poly and a second SDB over poly separated by one gate pitch) with no active device between the SDBs. As a result, the VT bridge structure provides a transition region between the VT devices with no source/drain/gate connections, which avoids DRC violations caused by abutment of different VT devices. The above features and other features of the present disclosure are discussed further below.

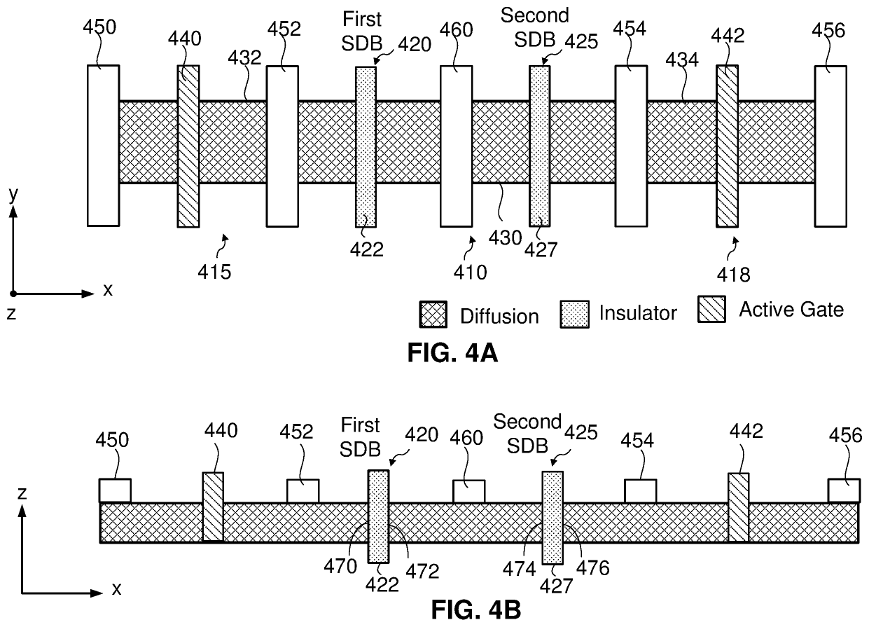

FIGS. 4A and 4B illustrate an example of a VT bridge structure 410 according to certain aspects of the present disclosure. FIG. 4A shows a top view of the VT bridge structure 410 and FIG. 4B shows a side view of the VT bridge structure 410.

In this example, the VT bridge structure 410 is placed between a first active device 415 (e.g., a first transistor) and a second active device 418 (e.g., a second transistor), in which the first active device 415 and the second active device 418 have different threshold voltages. For example, the first active device 415 may have a first threshold voltage and the second active device 418 may have a second threshold voltage, wherein the first threshold voltage is higher than the second threshold voltage. In one example, the first threshold voltage is at least 20 percent higher than the second threshold voltage. However, it is to be appreciated that the present disclosure is not limited to this example. As discussed further below, the VT bridge structure 410 allows the first active device 415 and the second active device 418 to be placed in the same row while avoiding DRC violations.

In this example, the VT bridge structure 410 includes a first single diffusion break (SDB) 420 and a second SDB 425. The first SDB 420 and the second SDB 425 may be separated by one gate pitch (i.e., distance between adjacent gates on the chip 100). Each of the first SDB 420 and the second SDB 425 extends in the y direction. In this example, the VT bridge structure 410 includes a first diffusion region 430 extending in the x direction between the first SDB 420 and the second SDB 425. The first diffusion region 430 is contiguous between the first SDB 420 and the second SDB 425 and may have a length in the x direction approximately equal to one gate pitch.

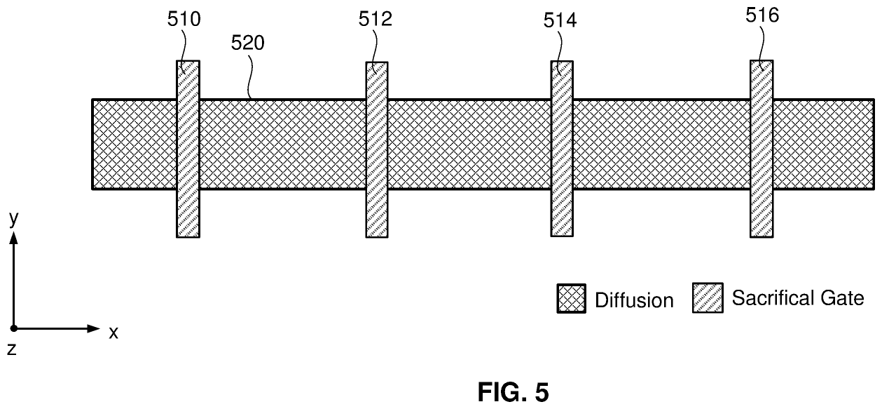

In this example, the first SDB 420 is disposed between the first diffusion region 430 and a second diffusion region 432 extending in the x direction. The first SDB 420 includes a first insulator 422 interposed between an edge 472 of the first diffusion region 430 and an edge 470 of the second diffusion region 432, as shown in FIG. 4B. The second SDB 425 is disposed between the first diffusion region 430 and a third diffusion region 434 extending in the x direction. The second SDB 425 includes a second insulator 427 interposed between an edge 474 of the first diffusion region 430 and an edge 476 of the third diffusion region 434, as shown in FIG. 4B. An edge may also be referred to as a sidewall or another term. Each of the insulators 422 and 427 may include silicon nitride (SiN), silicon dioxide (SiO2), or another insulating material. As discussed further below with reference to FIG. 5, the first SDB 420 and the second SDB 425 may replace two adjacent sacrificial gates (e.g., poly gates) on the chip 100.

In this example, the first active device 415 includes a gate 440 formed on the second diffusion region 432 in which a first portion of the second diffusion region 432 to the left of the gate 440 provides a first source/drain of the first active device 415, and a second portion of the second diffusion region 432 to the right of the gate 440 provides a second source/drain of the first active device 415. The first active device 415 also includes a first contact 450 disposed on the first portion of the second diffusion region 432, and a second contact 452 disposed on the second portion of the second diffusion region 432. The contacts 450 and 452 provide source/drain contacts for the first active device 415 and may be formed from the MD contact layer discussed above. The gate 440 may include a stack of one or more gate metal layers in which the composition and thicknesses of the gate metal layers may be specified by the process technology to achieve the first threshold voltage discussed above.

In this example, the second active device 418 includes a gate 442 formed on the third diffusion region 434 in which a first portion of the third diffusion region 434 to the left of the gate 442 provides a first source/drain of the second active device 418, and a second portion of the third diffusion region 434 to the right of the gate 442 provides a second source/drain of the second active device 418. The second active device 418 also includes a first contact 454 disposed on the first portion of the third diffusion region 434, and a second contact 456 disposed on the second portion of the third diffusion region 434. The contacts 454 and 456 provide source/drain contacts for the second active device 418 and may be formed from the MD contact layer discussed above. The gate 442 may include a stack of one or more gate metal layers in which the composition and thicknesses of the gate metal layers may be specified by the process technology to achieve the second threshold voltage discussed above.

In the example in FIGS. 4A and 4B, the VT bridge structure 410 also includes a contact 460 extending over the first diffusion region 430 between the first SDB 420 and the second SDB 425. The contact 460 may be formed from the MD contact layer. In this example, the contacts 450, 452, 460, 454, and 456 may be uniformly spaced in the x direction, as shown in FIG. 4A. In this example, the contact 460 may be electrically floating (i.e., not coupled to a signal path or a power rail) since the VT bridge structure 410 does not have an active device.

Although all of the contacts 450, 452, 460, 454, and 456 are shown as topside contacts in the example in FIGS. 4A and 4B, it is to be appreciated that the present disclose is not limited to this example. For example, in some implementations, one or more of the contacts 450, 452, 460, 454, and 456 may be a backside contact formed from the backside contact layer BSC shown in FIG. 1B.

In this example, the VT bridge structure 410 has no source/drain/gate connections. This is because the VT bridge structure 410 replaces two gates with the first and second SDBs 420 and 425 and the contact 460 between the first and second SDBs 420 and 425 is floating. As a result, the VT bridge structure 410 provides a transition region between the first active device 415 and the second active device 418 having no active device and no source/drain/gate connections, which avoids DRC violations caused by the abutment of devices with different threshold voltage. Therefore, the VT bridge structure 410 allows the first and second active devices 415 and 418 (which have different threshold voltages) to be placed in the same row while avoiding DRC violations.

In the example in FIGS. 4A and 4B, the first and second SDBs 420 and 425 replace two adjacent gates (also referred to as fingers). Thus, the VT bridge structure 410 in this example needs an area spanning approximately two gate pitches in the x direction. This area is significantly smaller than the area of a tap structure, which can span five or more gate pitches in the x direction. Thus, the VT bridge structure 410 improves layout efficiency compared with the approach of placing a tap structure between the active devices 415 and 418.

As discussed above, the first SDB 420 and the second SDB 425 may replace two adjacent gates on the chip 100. In this regard, FIG. 5 shows a top view of a diffusion region 520 extending in the x direction and gates 510, 512, 514, and 516 formed on the diffusion region 520. The gates 510, 512, 514, and 516 extend in the y direction and are uniformly spaced apart in the x direction by the gate pitch. The gates 510, 512, 514, and 516 may include polysilicon (i.e., poly gates) or another material. The structure shown in FIG. 5 is modified by subsequent process steps to form the VT bridge structure 410 and the active devices 415 and 418, as discussed further below.

In this example, the gates 512 and 514 are sacrificial gates that are etched away and replaced by the first SDB 420 and the second SDB 425. For example, etchant may be applied directly over the gate 512 to etch away the gate 512 and the underlying portion of the diffusion region 520 (e.g., using plasma etching or another type of etching). The resulting opening or cavity may then be filled with insulating material (e.g., SiN, SO2, etc.) to form the first SDB 420 shown in FIGS. 4A and 4B. Similarly, etchant may be applied directly over the gate 514 to etch away the gate 514 and the underlying portion of the diffusion region 520 (e.g., using plasma etching or another type of etching). The resulting opening or cavity may then be filled with insulating material (e.g., SiN, SO2, etc.) to form the second SDB 425 shown in FIGS. 4A and 4B. In this example, each of the SDB 420 and the second SDB 425 may also be referred to as SDB over poly for the example where the sacrificial gates 512 and 514 are made of polysilicon. In this example, the first SDB 420 and the second SDB 425 are spaced apart by one gate pitch (also referred to as one poly pitch) in the x direction. The length of each of the first SDB 420 and the second SDB 425 in the x direction may be approximately equal to the length of one gate in the x direction.

In this example, the gates 510 and 516 are replaced with the gates 440 and 442, respectively, shown in FIGS. 4A and 4B in a gate-last process. For example, the gate-last process may include etching away the gates 510 and 516 (e.g., poly gates) and then forming the gates 440 and 442 in place of the gates 510 and 516. However, it is to be appreciated that the present disclosure is not limited to this example.

In the example shown in FIGS. 4A and 4B, the distance between the gate 440 of the first active device 415 and the first SDB 420 in the x direction, the distance between the first SDB 420 and the second SDB 425 in the x direction, and the distance between the second SDB 425 and the gate 442 of the second active device 418 in the x direction are approximately equal to one another (e.g., approximately equal to one gate pitch). This is because the first SDB 420 and the second SDB 425 replace the gates 512 and 514, and the gates 510, 512, 514, and 516 are uniformly spaced apart in the x direction in this example.

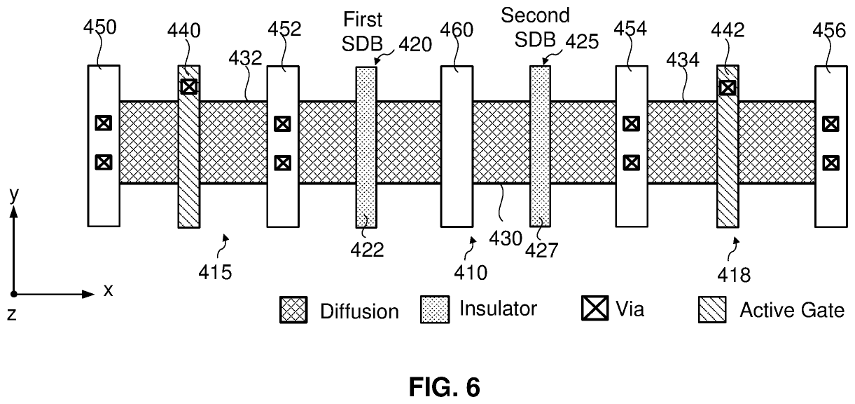

FIG. 6 shows an example of vias (e.g., VD) disposed on the contacts 450, 452, 454, and 456 of the active devices 415 and 418. For example, the vias may be used to couple sources and/or drains of the active devices 415 and 418 to metal tracks (not shown in FIG. 6) in metal layer M0 (e.g., for signal routing to and/or from the devices 415 and 418, power delivery, etc.). In this example, there is no via disposed on the contact 460 between the first SDB 420 and the second SDB 425 since this contact is floating and not used for a source/drain connection, as discussed above. Although the vias on the contacts 450, 452, 454, and 456 are shown being aligned in the y direction in FIG. 6, it is to be appreciated that the vias may be staggered (e.g., to couple the contacts 450, 452, 454, and 456 to different metal tracks in metal layer M0).

FIG. 6 also shows an example of vias disposed on the active gates 440 and 442 of the devices 415 and 418. For example, the vias may be used to couple the gates 440 and 442 to metal tracks (not shown in FIG. 6) in metal layer M0 (e.g., for signal routing to the gates 440 and 442).

Although FIGS. 4A, 4B and 6 show an example of one gate (i.e., gate 440) of the first active device 415, it is to be appreciated that the first active device 415 is not limited to one gate. In some implementations, the first active device 415 may include multiple gates spaced apart in the x direction in some implementations. Similarly, the second active device 418 may include multiple gates spaced apart in the x direction in some implementations.

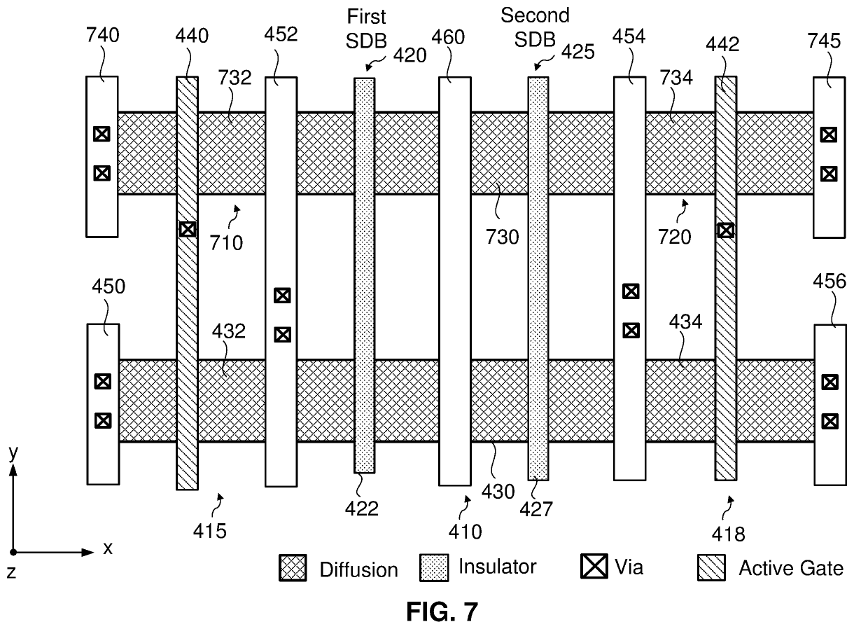

In some implementations, the VT bridge structure 410 may be extended in the y direction. In this regard, FIG. 7 shows an example in which the VT bridge structure 410 is also placed between a third active device 710 and a fourth active device 720 where the third and fourth active devices 710 and 720 are spaced apart from the first and second active devices 415 and 418 in the y direction. In certain aspects, the first and second active devices 415 and 418 may be n-type active devices and the third and fourth active devices 710 and 720 may be p-type active devices, or vice versa.

The third active device 710 and the fourth active device 720 may have different threshold voltages. For example, the third active device 710 may have a third threshold voltage and the fourth active device 720 may have a fourth threshold voltage, wherein the third threshold voltage is higher than the fourth threshold voltage. In one example, the third threshold voltage is at least 20 percent higher than the fourth threshold voltage. However, it is to be appreciated that the present disclosure is not limited to this example.

In this example, the VT bridge structure 410 includes a fourth diffusion region 730 between the first SDB 420 and the second SDB 425, in which the fourth diffusion region 730 is spaced apart from the first diffusion region 430 in the y direction. The fourth diffusion region 730 is contiguous between the first SDB 420 and the second SDB 425 and may have a length in the x direction approximately equal to one gate pitch. In the example shown in FIG. 7, the contact 460 (which is electrically floating) extends in the y direction across the fourth diffusion region 730. However, it is to be appreciated that the present disclosure is not limited to this example.

In this example, the third active device 710 includes a fifth diffusion region 732, and the fourth active device 720 includes a sixth diffusion region 734, in which the VT bridge structure 410 is between the fifth diffusion region 732 and the sixth diffusion region 734. In the example in FIG. 7, the gate 440 extends across the fifth diffusion region 732 in the y direction. Thus, in this example, the gate 440 is shared by the first active device 415 and the third active device 710 (i.e., the gate is common to the active devices 415 and 710). However, it is to be appreciated that the present disclosure is not limited to this example.

In this example, a first portion of the fifth diffusion region 732 to the left of the gate 440 provides a first source/drain of the third active device 710, and a second portion of the fifth diffusion region 732 to the right of the gate 440 provides a second source/drain of the third active device 710. The third active device 710 also includes a contact 740 disposed on the first portion of the fifth diffusion region 732 to provide a first source/drain contact for the third active device 710. In this example, the second contact 452 of the first active device 415 may extend across the second portion of the fifth diffusion region 732 in the y direction to provide a second source/drain contact for the third active device 710. In this example, the contact 452 is shared by the first active device 415 and the third active device 710. However, it is to be appreciated that the present disclosure is not limited to this example.

In some implementations, the first active device 415 and the third active device 710 may be used to implement a complementary inverter, in which the first active device 415 is an n-type active device (e.g., the second diffusion region 432 is an n-type diffusion region) and the third active device 710 is a p-type active device (e.g., the fifth diffusion region 732 is a p-type diffusion region). In this example, the gate 440 (which is common to the active devices 415 and 710) provides the input of the inverter, the contact 450 may be coupled to a ground rail (e.g., formed in metal layer M0), the contact 740 may be coupled to a voltage supply rail (e.g., formed in metal layer M0), and the contact 452 may provide the output of the inverter. However, it is to be appreciated that the present disclosure is not limited to this example.

In the example in FIG. 7, the gate 442 extends across the sixth diffusion region 734 in the y direction. Thus, in this example, the gate 442 is shared by the second active device 418 and the fourth active device 720 (i.e., the gate is common to the active devices 418 and 720). However, it is to be appreciated that the present disclosure is not limited to this example.

In this example, a first portion of the sixth diffusion region 734 to the left of the gate 442 provides a first source/drain of the fourth active device 720, and a second portion of the sixth diffusion region 734 to the right of the gate 442 provides a second source/drain of the fourth active device 720. The fourth active device 720 also includes a contact 745 disposed on the second portion of the sixth diffusion region 734 to provide a source/drain contact for the fourth active device 720. In this example, the first contact 454 of the second active device 418 may extend across the first portion of the sixth diffusion region 734 in the y direction to provide a source/drain contact for the fourth active device 720. In this example, the contact 454 is shared by the second active device 418 and the fourth active device 720. However, it is to be appreciated that the present disclosure is not limited to this example.

In some implementations, the second active device 418 and the fourth active device 720 may be used to implement a complementary inverter, in which the second active device 418 is an n-type active device (e.g., the third diffusion region 434 is an n-type diffusion region) and the fourth active device 720 is a p-type active device (e.g., the sixth diffusion region 734 is a p-type diffusion region). In this example, the gate 442 (which is common to the active devices 418 and 720) provides the input of the inverter, the contact 456 may be coupled to a ground rail (e.g., formed in metal layer M0), the contact 745 may be coupled to a voltage supply rail (e.g., formed in metal layer M0), and the contact 454 may provide the output of the inverter. However, it is to be appreciated that the present disclosure is not limited to this example.

It is to be appreciated that the present disclosure is not limited to the example shown in FIG. 7. For example, in other implementations, the gate 440 may be cut between the second diffusion region 432 and the fifth diffusion region 732, and/or the contact 452 may be cut between the second diffusion region 432 and the fifth diffusion region 732. Also, the gate 442 may be cut between the third diffusion region 434 and the sixth diffusion region 734, and/or the contact 454 may be cut between the third diffusion region 434 and the sixth diffusion region 734. Also, the contact 460 may be cut between the first diffusion region 430 and the fourth diffusion region 730.

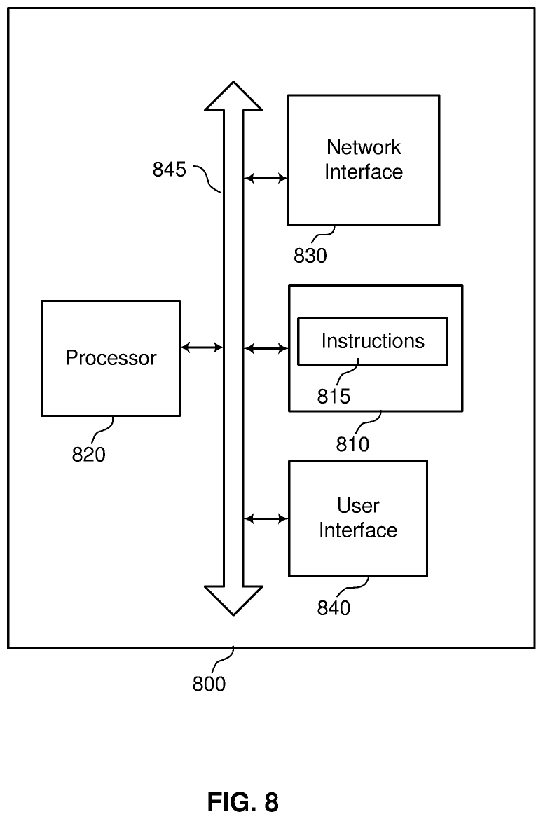

In certain aspects, the exemplary layouts discussed above may be determined using a computer system. In this regard, FIG. 8 illustrates a computer system 800 that may be used to determine layouts for the chip 100 according to certain aspects. The computer system 800 may include a processor 820, a memory 810, a network interface 830, and a user interface 840. These components may be in electronic communication via one or more buses 845.

The memory 810 may store instructions 815 that are executable by the processor 820 to cause the computer system 800 to perform one or more of the operations described herein. The processor 820 may include a general-purpose processor, a digital signal processor (DSP), a central processing unit (CPU), a microcontroller, an application specific integrated circuit (ASIC), a field programmable gate array (FPGA), a programmable logic device, a discrete gate or transistor logic component, a discrete hardware component, or any combination thereof.

The memory 810 may include, by way of example, random access memory (RAM), flash memory, read only memory (ROM), programmable read only memory (PROM), erasable programmable read only memory (EPROM), electrically erasable programmable read only memory (EEPROM), registers, magnetic disks, optical disks, hard drives, or any other suitable storage medium, or any combination thereof. The memory 810 may also store a cell library including files specifying layouts for various cells that may be placed on the chip 100 including layouts of the VT bridge structure 410, the first active device 415, and the second active device 418.

The network interface 830 is configured to interface the computer system 800 with one or more other devices. The user interface 840 may be configured to receive data from a user (e.g., via keypad, mouse, etc.) and provide the data to the processor 820. The user interface 840 may also be configured to output data from the processor 820 to the user (e.g., via a display, a speaker, etc.).

Implementation examples are described in the following numbered clauses:

1. A chip, comprising:
a first active device having a first threshold voltage;
a second active device having a second threshold voltage, wherein the first threshold voltage is higher than the second threshold voltage; and
a bridge structure between the first active device and the second active device, wherein the bridge structure comprises:
   a first single diffusion break (SDB);
   a second SDB; and
   a first diffusion region extending in a first direction between the first SDB and the second SDB.

2. The chip of clause 1, wherein the first threshold voltage is at least 20 percent higher than the second threshold voltage.

3. The chip of clause 1 or 2, wherein the first active device comprises:
a second diffusion region extending in the first direction; and
a first gate extending across the second diffusion region in a second direction perpendicular to the first direction.

4. The chip of clause 3, wherein a distance between the first gate and the first SDB in the first direction is approximately equal to a distance between the first SDB and the second SDB in the first direction.

5. The chip of clause 3 or 4, wherein a length of the first SDB in the first direction is approximately equal to a length of the first gate in the first direction.

6. The chip of any one of clauses 3 to 5, wherein the first SDB comprises an insulator disposed between an edge of the first diffusion region and an edge of the second diffusion region.

7. The chip of clause 6, wherein the insulator comprises at least one of silicon nitride and silicon oxide.

8. The chip of any one of clauses 3 to 7, wherein the second active device comprises:
a third diffusion region extending in the first direction; and
a second gate extending across the third diffusion region in the second direction.

9. The chip of clause 8, wherein a distance between the first gate and the first SDB in the first direction is approximately equal to a distance between the first SDB and the second SDB in the first direction, and the distance between the first SDB and the second SDB in the first direction is approximately equal to a distance between the second SDB and the second gate in the first direction.

10. The chip of clause 8 or 9, wherein:
the first active device includes a first contact disposed on the second diffusion region between the first gate and the first SDB;
the second active device includes a second contact disposed on the third diffusion region between the second SDB and the second gate; and
the bridge structure comprises a third contact disposed on the first diffusion region between the first SDB and the second SDB, wherein the third contact is electrically floating.

11. The chip of clause 10, wherein the first contact, the second contact, and the third contact are formed from a same contact layer.

12. The chip of any one of clauses 8 to 11, wherein a length of the first SDB in the first direction and a length of the second SDB in the first direction are each approximately equal to a length of the first gate in the first direction.

13. The chip of any one of clauses 8 to 12, wherein the first SDB comprises a first insulator disposed between an edge of the second diffusion region and a first edge of the first diffusion region, and the second SDB comprises a second insulator disposed between a second edge of the first diffusion region and an edge of the third diffusion region.

14. The chip of clause 13, wherein each of the first insulator and the second insulator comprises at least one of silicon nitride and silicon oxide.

15. The chip of any one of clauses 1 to 14, wherein the first active device comprises a first gate-all-around field-effect transistor (GAAFET) and the second active device comprises a second GAAFET.

16. The chip of any one of clauses 1 to 14, wherein the first active device comprises a first fin field-effect transistor (FinFET) and the second active device comprises a second FinFET.

17. The chip of any one of clauses 1 to 16, further comprising:
a third active device having a third threshold voltage; and
a fourth active device having a fourth threshold voltage, wherein the third threshold voltage is higher than the fourth threshold voltage, and the bridge structure is between the third active device and the fourth active device.

18. The chip of clause 17, wherein each of the first active device and the second active device is an n-type active device, and each of the third active device and the fourth active device is a p-type active device.

19. The chip of clause 17 or 18, wherein the bridge structure further comprises a second diffusion region extending in the first direction between the first SDB and the second SDB, and the second diffusion region is spaced apart from the first diffusion region in a second direction perpendicular to the first direction.

20. The chip of clause 19, wherein the first active device and the third active device comprise:
a third diffusion region extending in the first direction;
a fourth diffusion region extending in the first direction, wherein the third diffusion region is spaced apart from the fourth diffusion region in the second direction; and
gate extending across the third diffusion region and the fourth diffusion region in the second direction.

21. The chip of clause 20, wherein the third diffusion region is an n-type diffusion region, and the fourth diffusion region is a p-type diffusion region.

22. The chip of clause 20 or 21, wherein a distance between the gate and the first SDB in the first direction is approximately equal to a distance between the first SDB and the second SDB in the first direction.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a first active device having a first threshold voltage;
a second active device having a second threshold voltage, wherein the first threshold voltage is higher than the second threshold voltage; and
a bridge structure between the first active device and the second active device, wherein the bridge structure comprises:
a first single diffusion break (SDB);
a second SDB; and
a first diffusion region extending in a first direction between the first SDB and the second SDB.

2. The chip of claim 1, wherein the first threshold voltage is at least 20 percent higher than the second threshold voltage.

3. The chip of claim 1, wherein the first active device comprises:
a second diffusion region extending in the first direction; and
a first gate extending across the second diffusion region in a second direction perpendicular to the first direction.

4. The chip of claim 3, wherein a distance between the first gate and the first SDB in the first direction is approximately equal to a distance between the first SDB and the second SDB in the first direction.

5. The chip of claim 3, wherein a length of the first SDB in the first direction is approximately equal to a length of the first gate in the first direction.

6. The chip of claim 3, wherein the first SDB comprises an insulator disposed between an edge of the first diffusion region and an edge of the second diffusion region.

7. The chip of claim 6, wherein the insulator comprises at least one of silicon nitride and silicon oxide.

8. The chip of claim 3, wherein the second active device comprises:
a third diffusion region extending in the first direction; and
a second gate extending across the third diffusion region in the second direction.

9. The chip of claim 8, wherein a distance between the first gate and the first SDB in the first direction is approximately equal to a distance between the first SDB and the second SDB in the first direction, and the distance between the first SDB and the second SDB in the first direction is approximately equal to a distance between the second SDB and the second gate in the first direction.

10. The chip of claim 8, wherein:
the first active device includes a first contact disposed on the second diffusion region between the first gate and the first SDB;
the second active device includes a second contact disposed on the third diffusion region between the second SDB and the second gate; and
the bridge structure comprises a third contact disposed on the first diffusion region between the first SDB and the second SDB, wherein the third contact is electrically floating.

11. The chip of claim 10, wherein the first contact, the second contact, and the third contact are formed from a same contact layer.

12. The chip of claim 8, wherein a length of the first SDB in the first direction and a length of the second SDB in the first direction are each approximately equal to a length of the first gate in the first direction.

13. The chip of claim 8, wherein the first SDB comprises a first insulator disposed between an edge of the second diffusion region and a first edge of the first diffusion region, and the second SDB comprises a second insulator disposed between a second edge of the first diffusion region and an edge of the third diffusion region.

14. The chip of claim 13, wherein each of the first insulator and the second insulator comprises at least one of silicon nitride and silicon oxide.

15. The chip of claim 1, wherein the first active device comprises a first gate-all-around field-effect transistor (GAAFET) and the second active device comprises a second GAAFET.

16. The chip of claim 1, wherein the first active device comprises a first fin field-effect transistor (FinFET) and the second active device comprises a second FinFET.

17. The chip of claim 1, further comprising:
a third active device having a third threshold voltage; and
a fourth active device having a fourth threshold voltage, wherein the third threshold voltage is higher than the fourth threshold voltage, and the bridge structure is between the third active device and the fourth active device.

18. The chip of claim 17, wherein each of the first active device and the second active device is an n-type active device, and each of the third active device and the fourth active device is a p-type active device.

19. The chip of claim 17, wherein the bridge structure further comprises a second diffusion region extending in the first direction between the first SDB and the second SDB, and the second diffusion region is spaced apart from the first diffusion region in a second direction perpendicular to the first direction.

20. The chip of claim 19, wherein the first active device and the third active device comprise:
a third diffusion region extending in the first direction;
a fourth diffusion region extending in the first direction, wherein the third diffusion region is spaced apart from the fourth diffusion region in the second direction; and
gate extending across the third diffusion region and the fourth diffusion region in the second direction.

21. The chip of claim 20, wherein the third diffusion region is an n-type diffusion region, and the fourth diffusion region is a p-type diffusion region.

22. The chip of claim 20, wherein a distance between the gate and the first SDB in the first direction is approximately equal to a distance between the first SDB and the second SDB in the first direction.
